(19) United States
(12) Patent Application Publication
(10) Pub. No.: US 2005/0272252 A1
(43) Pub. Date: Dec. 8, 2005

(54) Circuit device

(76) Inventors: Ryosuke Usui, Ichinomiya-shi (JP); Hideki Mizuhara, Ichinomiya-shi (JP); Yasunori Inoue, Ogaki-shi (JP); Yusuke Igarashi, Isesaki-shi (JP); Takeshi Nakamura, Isesaki-shi (JP)

Correspondence Address: MCDERMOTT WILL & EMERY LLP, 600 13TH STREET, N.W., WASHINGTON, DC, 20005-3096, US

(21) Appl. No.: 11/139,036

(22) Filed: May 27, 2005

(30) Foreign Application Priority Data
May 28, 2004 (JP) 2004-158891
May 28, 2004 (JP) 2004-158911
May 28, 2004 (JP) 2004-158916

(51) Int. Cl. H01L 21/4763

(52) U.S. Cl. 438/624

(57) ABSTRACT

Provided is a circuit device capable of inhibiting an insulating layer from separating from a substrate. This circuit device comprises a substrate mainly constituted of metal including a first metal layer having a first thermal expansion coefficient, a second metal layer, formed on the first metal layer, having a second thermal expansion coefficient different from the first thermal expansion coefficient of the first metal layer and a third metal layer, formed on the second metal layer, having a third thermal expansion coefficient different from the second thermal expansion coefficient of the second metal layer, an insulating layer formed on the substrate, a conductive layer formed on the insulating layer and a circuit element electrically connected to the conductive layer.

### BACKGROUND OF THE INVENTION

1. Field of the Invention

The present invention relates to a circuit device, and more particularly, it relates to a circuit device comprising a circuit element.

2. Description of the Background Art

In a circuit device included in an electronic instrument or the like, the exothermic density per unit volume has recently been increased due to downsizing, densification and multi-functionalization. In recent years, therefore, a metal substrate having high heat releasability has been employed as the substrate for this type of circuit device so that circuit elements such as an IC (integrated circuit) and an LSI (large-scale integrated circuit) are mounted on the metal substrate, as disclosed in Japanese Patent Laying-Open No. 8-288605 (1996), for example. A structure obtained by forming a hybrid IC (integrated circuit) on a metal substrate is also known in general. The term “hybrid IC” denotes a circuit device obtained by collectively integrating circuit elements such as IC chips, capacitors, resistors etc. onto a single substrate.

FIG. 16 is a sectional view schematically showing the structure of a conventional circuit device disclosed in the aforementioned Japanese Patent Laying-Open No. 8-288605. Referring to FIG. 16, a resin layer 102 functioning as an insulating layer containing silica (SiO₂) added as a filler is formed on a metal substrate 101 of aluminum (Al) in the conventional circuit device. An IC chip 104 employing a silicon substrate (not shown) is mounted on a prescribed region of the resin layer 102 through a bonding layer 103 of resin. Metal wires 105 of copper are formed on regions of the resin layer 102 separated from ends of the IC chip 104 at prescribed intervals through the bonding layer 103. The metal wires 105 and the metal substrate 101 are insulated from each other through the resin layer 102. The metal wires 105 and the IC chip 104 are electrically connected with each other through wires 106.

In the conventional circuit device shown in FIG. 16, the metal substrate 101 of aluminum (Al) is employed while the IC chip 104 is mounted on the metal substrate 101 through the resin layer 102, so that a large quantity of heat generated from the IC chip 104 can be released through the metal substrate 101.

In the conventional circuit device obtained by forming the resin layer (insulating layer) 102 and the IC chip 104 employing the silicon substrate on the metal substrate 101 of aluminum (Al), however, the thermal expansion coefficient of the metal substrate 101 is disadvantageously remarkably different from those of the resin layer (insulating layer) 102 and the IC chip 104. Consequently, the resin layer (insulating layer) 102 disadvantageously easily separates from the metal substrate 101 due to the difference in thermal expansion coefficient between the metal substrate 101 and the resin layer (insulating layer) 102 and the IC chip 104.

### SUMMARY OF THE INVENTION

The present invention has been proposed in order to solve the aforementioned problem, and an object of the present invention is to provide a circuit device capable of inhibiting an insulating layer from separating from a substrate.

In order to attain the aforementioned object, a circuit device according to a first aspect of the present invention comprises a substrate mainly constituted of metal including a first metal layer having a first thermal expansion coefficient, a second metal layer, formed on the first metal layer, having a second thermal expansion coefficient different from the first thermal expansion coefficient of the first metal layer and a third metal layer, formed on the second metal layer, having a third thermal expansion coefficient different from the second thermal expansion coefficient of the second metal layer, an insulating layer formed on the substrate, a conductive layer formed on the insulating layer and a circuit element electrically connected to the conductive layer.

In the circuit device according to the first aspect, as hereinabove described, the substrate mainly constituted of metal including the first metal layer having the first thermal expansion coefficient, the second metal layer, formed on the first metal layer, having the second thermal expansion coefficient different from the first thermal expansion coefficient of the first metal layer and the third metal layer, formed on the second metal layer, having the third thermal expansion coefficient different from the second thermal expansion coefficient of the second metal layer is so employed that the thermal expansion coefficient of the substrate mainly constituted of metal including the first to third metal layers can be controlled by adjusting the thicknesses of the first, second and third metal layers respectively. When the thicknesses of the first to third metal layers are so adjusted that the thermal expansion coefficient of the substrate approaches both of the thermal expansion coefficients of the circuit element and the insulating layer, therefore, the insulating layer can be inhibited from separating from the substrate due to difference in thermal expansion coefficient between the substrate, the circuit element and the insulating layer.

In the aforementioned circuit device according to the first aspect, the thicknesses of the first metal layer, the second metal layer and the third metal layer constituting the substrate are preferably so adjusted that the thermal expansion coefficient of the substrate approaches both of the thermal expansion coefficient of the insulating layer and the thermal expansion coefficient of the circuit element. According to this structure, the insulating layer can be easily inhibited from separating from the substrate due to difference in thermal expansion coefficient between the substrate, the circuit element and the insulating layer.

In the aforementioned circuit device according to the first aspect, the second thermal expansion coefficient of the second metal layer is preferably smaller than the first thermal expansion coefficient of the first metal layer and the third thermal expansion coefficient of the third metal layer. According to this structure, the thermal expansion coefficient of the substrate including the first and third metal layers can be easily reduced through the second metal layer.

In the aforementioned circuit device according to the first aspect, the insulating layer preferably includes an insulating layer mainly composed of resin. According to this structure, the contact area between the substrate mainly constituted of metal and the insulating layer mainly composed of resin can be increased. Thus, the insulating layer can be inhibited from separating from the substrate although the same is mainly composed of resin having low adhesiveness to the substrate mainly constituted of metal.

In this case, a filler is preferably added to the insulating layer mainly composed of resin for increasing the thermal conductivity of the insulating layer. According to this structure, the thermal conductivity of the insulating layer mainly composed of resin is so increased that heat releasability of the insulating layer mainly composed of resin can be improved.

In the aforementioned circuit device according to the first aspect, the insulating layer preferably includes an opening provided in a region located under the circuit element to reach the surface of the substrate, and the conductive layer provided on the insulating layer is preferably formed to be in contact with the surface of the substrate through the opening and preferably has a function of transferring heat to the substrate through the opening. According to this structure, a large quantity of heat generated from the circuit element can be easily released toward the substrate through the conductive layer in contact with the surface of the substrate.

In this case, the components of the first metal layer and the third metal layer are preferably identical to the component of the conductive layer. According to this structure, the first and third metal layers of materials substantially identical to the component of the conductive layer hold the second metal layer therebetween so that a plating solution can be inhibited from deterioration resulting from elution of the component of the second metal layer in the plating solution when the conductive layer is formed by plating. In this case, the term “identical” includes a case of “substantially identical” in a range capable of attaining the object of inhibiting the plating solution from deterioration.

In the aforementioned circuit device according to the first aspect, the insulating layer preferably includes a first insulating layer formed on the substrate and a second insulating layer formed on the first insulating layer, and the conductive layer preferably includes a first conductive layer formed between the first insulating layer and the second insulating layer and a second conductive layer formed on the second insulating layer. According to this structure, the first and second conductive layers can be insulated from each other through the second insulating layer. When the first and second conductive layers are employed as wires and the wires formed by the first and second conductive layers intersect with each other in a plan view, therefore, the wires formed by the first and second conductive layers can be inhibited from an electric short circuit. Consequently, the degree of freedom in extension of the wires as well as the wiring density thereof can be improved.

In this case, the circuit device preferably further includes a first wire constituted of the first conductive layer and a second wire constituted of the second conductive layer, and the first wire and the second wire preferably intersect with each other in a plan view. According to this structure, the degree of freedom in extension of the first and second wires as well as the wiring density thereof can be easily improved.

In the aforementioned circuit device according to the first aspect, the substrate preferably has a corrugated surface. According to this structure, the contact area between the substrate and the insulating layer can be increased. Thus, adhesiveness between the substrate and the insulating layer can be improved. Consequently, the insulating layer can be further inhibited from separating from the substrate. When the insulating layer is mainly composed of resin, a filler is added to the insulating layer and the contact area between the substrate and the insulating layer is reduced due to the filler added to the insulating layer and located in the vicinity of the interface between the insulating layer and the substrate, the contact area between the substrate and the insulating layer is increased due to the corrugated surface of the substrate. Thus, the adhesiveness between the substrate and the insulating layer can be inhibited from reduction despite the filer added to the insulating layer mainly composed of resin.

In the aforementioned circuit device according to the first aspect, the surface of the substrate is preferably oxidized or nitrided. According to this structure, the oxidized or nitrided surface of the substrate functions as another insulating layer when the insulating layer located between the substrate mainly constituted of metal and the conductive layer is deteriorated in insulation property, whereby the dielectric voltage between the substrate mainly constituted of metal and the conductive layer can be inhibited from reduction.

A circuit device according to a second aspect of the present invention comprises a substrate, having a corrugated surface, mainly constituted of metal, an insulating layer formed on the corrugated surface of the substrate, a conductive layer formed on the insulating layer and a circuit element electrically connected to the conductive layer.

In the circuit device according to the second aspect, as hereinabove described, the substrate is formed to have the corrugated surface and the insulating layer is formed on the corrugated surface of the substrate, whereby the contact area between the substrate mainly constituted of metal and the insulating layer can be increased. Thus, the adhesiveness between the substrate and the insulating layer can be improved. Consequently, the insulating layer can be inhibited from separating from the substrate.

In the aforementioned circuit device according to the second aspect, the insulating layer preferably includes an insulating layer mainly composed of resin. According to this structure, the contact area between the substrate mainly constituted of metal and the insulating layer mainly composed of resin can be increased. Thus, the insulating mainly composed of resin having low adhesiveness to the substrate mainly constituted of metal can be inhibited from separating from the substrate.

In this case, a filler is preferably added to the insulating layer mainly composed of resin for increasing the thermal conductivity of the insulating layer. According to this structure, the thermal conductivity of the insulating layer mainly composed of resin is so increased that heat releasability of the insulating layer mainly composed of resin can be improved. When the contact area between the substrate and the insulating layer is reduced due to the filler added to the insulating layer and located in the vicinity of the interface between the insulating layer and the substrate, the contact area between the substrate and the insulating layer is increased due to the corrugated surface of the substrate, whereby the adhesiveness between the substrate and the insulating layer can be inhibited from reduction despite the filer added to the insulating layer mainly composed of resin.

In the aforementioned circuit device according to the second aspect, the insulating layer preferably includes an opening provided in a region located under the circuit element to reach the surface of the substrate, and the conductive layer provided on the insulating layer is preferably formed to be in contact with the surface of the substrate through the opening and preferably has a function of transferring heat to the substrate through the opening. According to this structure, a large quantity of heat generated from the circuit element can be easily released toward the substrate through the conductive layer in contact with the surface of the substrate.

In the aforementioned circuit device according to the second aspect, the insulating layer preferably includes a first insulating layer formed on the surface of the substrate and a second insulating layer formed on the first insulating layer, and the conductive layer preferably includes a first conductive layer formed between the first insulating layer and the second insulating layer and a second conductive layer formed on the second insulating layer. According to this structure, the first and second conductive layers can be insulated from each other through the second insulating layer. When the first and second conductive layers are employed as wires and the wires formed by the first and second conductive layers intersect with each other in a plan view, therefore, the wires formed by the first and second conductive layers can be inhibited from an electric short circuit. Consequently, the degree of freedom in extension of the wires as well as the wiring density thereof can be improved.

In this case, the circuit device preferably further includes a first wire constituted of the first conductive layer and a second wire constituted of the second conductive layer, and the first wire and the second wire preferably intersect with each other in a plan view. According to this structure, the degree of freedom in extension of the first and second wires as well as the wiring density thereof can be easily improved.

In the aforementioned circuit device according to the second aspect, the substrate preferably includes a first metal layer having a first thermal expansion coefficient, a second metal layer, formed on the first metal layer, having a second thermal expansion coefficient different from the first thermal expansion coefficient of the first metal layer and a third metal layer, formed on the second metal layer, having a third thermal expansion coefficient different from the second thermal expansion coefficient of the second metal layer. According to this structure, the thermal expansion coefficient of the substrate including the first, second and third metal layers can be easily controlled by adjusting the thicknesses of the first, second and third metal layers respectively. When the thicknesses of the first to third metal layers are so adjusted that the thermal expansion coefficient of the substrate approaches both of the thermal expansion coefficients of the circuit element and the insulating layer, therefore, the insulating layer can be inhibited from separating from the substrate due to difference in thermal expansion coefficient between the substrate, the circuit element and the insulating layer.

In the aforementioned circuit device according to the second aspect, the corrugated surface of the substrate is preferably oxidized or nitrided. According to this structure, the oxidized or nitrided corrugated surface of the substrate functions as another insulating layer when the insulating layer located between the substrate mainly constituted of metal and the conductive layer is deteriorated in insulation property, whereby the dielectric voltage between the substrate mainly constituted of metal and the conductive layer can be inhibited from reduction.

A circuit device according to a third aspect of the present invention comprises a substrate, having an oxidized or nitrided surface, mainly constituted of metal, an insulating layer formed on the oxidized or nitrided surface of the substrate, a conductive layer formed on the insulating layer and a circuit element electrically connected to the conductive layer.

In the circuit device according to the third aspect, as hereinabove described, the surface of the substrate is oxidized or nitrided while the insulating layer is formed on the oxidized or nitrided surface of the substrate so that the oxidized or nitrided surface of the substrate functions as another insulating layer when the insulating layer located between the substrate mainly constituted of metal and the conductive layer is deteriorated in insulation property, whereby the dielectric voltage between the substrate mainly constituted of metal and the conductive layer can be inhibited from reduction.

In the aforementioned circuit device according to the third aspect, the oxidized or nitrided surface of the substrate is preferably formed in a corrugated shape. According to this structure, the contact area between the substrate and the insulating layer can be increased. Thus, adhesiveness between the substrate and the insulating layer can be improved. Consequently, the insulating layer can be inhibited from separating from the substrate. When the insulating layer is mainly composed of resin, a filler is added to the insulating layer and the contact area between the substrate and the insulating layer is reduced due to the filler added to the insulating layer and located in the vicinity of the interface between the insulating layer and the substrate, the contact area between the substrate and the insulating layer is increased due to the corrugated surface of the substrate. Thus, the adhesiveness between the substrate and the insulating layer can be inhibited from reduction despite the filer added to the insulating layer mainly composed of resin.

In the aforementioned circuit device according to the third aspect, the insulating layer preferably includes an insulating layer mainly composed of resin. According to this structure, the contact area between the substrate mainly constituted of metal and the insulating layer mainly composed of resin can be increased. Thus, the insulating layer can be inhibited from separating from the substrate although the same is mainly composed of resin having low adhesiveness to the substrate mainly constituted of metal.

In this case, a filler is preferably added to the insulating layer mainly composed of resin for increasing the thermal conductivity of the insulating layer. According to this structure, the thermal conductivity of the insulating layer mainly composed of resin is so increased that heat releasability of the insulating layer mainly composed of resin can be improved.

In the aforementioned circuit device according to the third aspect, the insulating layer preferably includes an opening provided in a region located under the circuit element to reach the surface of the substrate, and the conductive layer provided on the insulating layer is preferably formed to be in contact with the surface of the substrate through the opening and preferably has a function of transferring heat to the substrate through the opening. According to this structure, a large quantity of heat generated from the circuit element can be easily released toward the substrate through the conductive layer in contact with the surface of the substrate.

In the aforementioned circuit device according to the third aspect, the insulating layer preferably includes a first insulating layer formed on the surface of the substrate and a second insulating layer formed on the first insulating layer, and the conductive layer preferably includes a first conductive layer formed between the first insulating layer and the second insulating layer and a second conductive layer formed on the second insulating layer. According to this structure, the first and second conductive layers can be insulated from each other through the second insulating layer. When the first and second conductive layers are employed as wires and the wires formed by the first and second conductive layers intersect with each other in a plan view, therefore, the wires formed by the first and second conductive layers can be inhibited from an electric short circuit. Consequently, the degree of freedom in extension of the wires as well as the wiring density thereof can be improved.

In this case, the circuit device preferably further includes a first wire constituted of the first conductive layer and a second wire constituted of the second conductive layer, and the first wire and the second wire preferably intersect with each other in a plan view. According to this structure, the degree of freedom in extension of the first and second wires as well as the wiring density thereof can be easily improved.

In the aforementioned circuit device according to the third aspect, the substrate preferably includes a first metal layer having a first thermal expansion coefficient, a second metal layer, formed on the first metal layer, having a second thermal expansion coefficient different from the first thermal expansion coefficient of the first metal layer and a third metal layer, formed on the second metal layer, having a third thermal expansion coefficient different from the second thermal expansion coefficient of the second metal layer. According to this structure, the thermal expansion coefficient of the substrate including the first, second and third metal layers can be easily controlled by adjusting the thicknesses of the first, second and third metal layers respectively. When the thicknesses of the first to third metal layers are so adjusted that the thermal expansion coefficient of the substrate approaches both of the thermal expansion coefficients of the circuit element and the insulating layer, therefore, the insulating layer can be inhibited from separating from the substrate due to difference in thermal expansion coefficient between the substrate, the circuit element and the insulating layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing a hybrid integrated circuit device (hybrid IC) according to an embodiment of the present invention;

FIG. 2 is a sectional view taken along the line 100-100 in FIG. 1;

FIGS. 3 to 15 are sectional views for illustrating a process of fabricating the hybrid integrated circuit device according to the embodiment shown in FIG. 2; and

FIG. 16 is a sectional view schematically showing the structure of a conventional circuit device.

### DESCRIPTION OF THE PREFERRED EMBODIMENTS

An embodiment of the present invention is now described with reference to the drawings.

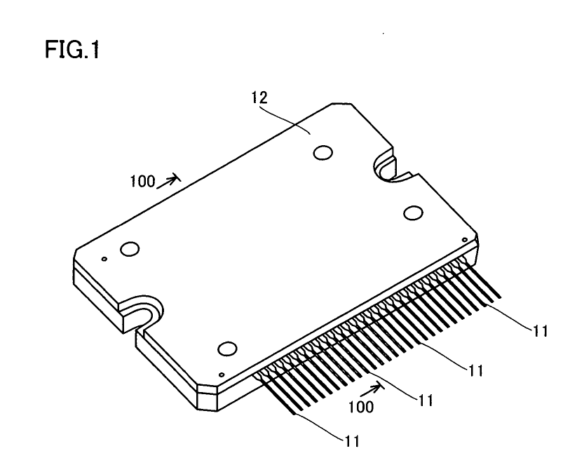

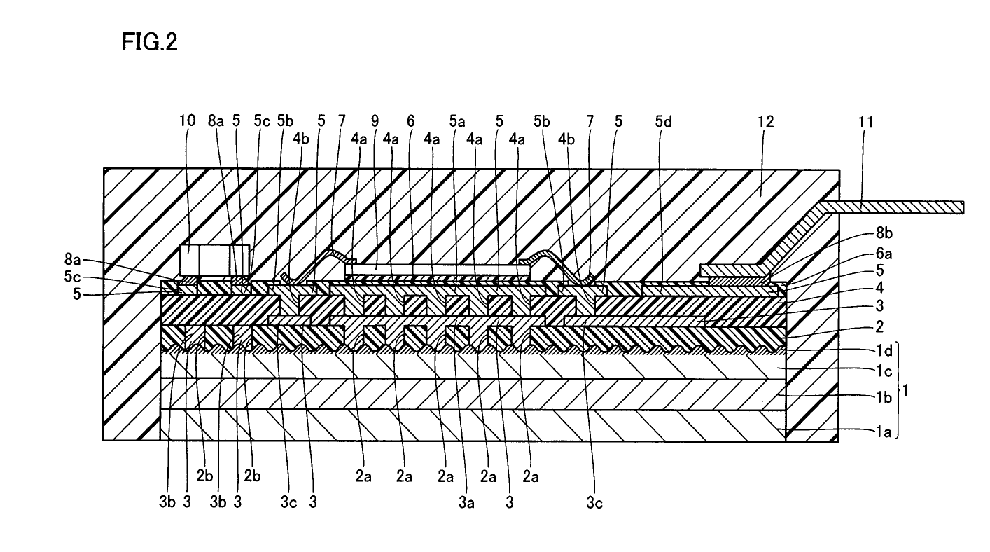

First, the structure of a hybrid integrated circuit device according to this embodiment is described with reference to FIGS. 1 and 2.

In the hybrid integrated circuit device according to this embodiment, a substrate 1 of a multilayer structure (three-layer structure) having a thickness of about 100 μm to about 3 mm (about 1.5 mm, for example) is employed as shown in FIG. 2. This substrate 1 is constituted of a cladding material prepared by stacking a lower metal layer 1a of copper, an intermediate metal layer 1b of an Fe—Ni alloy (the so-called invar alloy) formed on the lower metal layer 1a and an upper metal layer 1c of copper formed on the intermediate metal layer 1b. The lower and upper metal layers 1a and 1c of copper have thermal expansion coefficients of about 12 ppm/° C. The intermediate metal layer 1b of the invar alloy consists of the alloy of Fe containing about 36% of Ni and has a small thermal expansion coefficient of about 0.2 ppm/° C. to about 5 ppm/° C. In other words, the thermal expansion coefficient (about 0.2 ppm/° C. to about 5 ppm/° C.) of the intermediate metal layer 1b is smaller than the thermal expansion coefficients (about 12 ppm/° C.) of the lower and upper metal layers 1a and 1c. The thicknesses of the lower, intermediate and upper metal layers 1a, 1b and 1c are adjusted in the ratios 1:1:1, so that the thermal expansion coefficient of the substrate 1 is about 6 ppm/° C. to about 8 ppm/° C. The lower, intermediate and upper metal layers 1a, 1b and 1c are examples of the “first metal layer”, the “second metal layer” and the “third metal layer” in the present invention respectively.

According to this embodiment, a copper oxide film 1d having a thickness of about 0.1 μm to about 0.3 μm is formed on the surface of the upper metal layer 1c, i.e., the uppermost one of the three metal layers 1a to 1c constituting the substrate 1. This copper oxide film 1d is formed by oxidizing the surface of the upper metal layer 1c. According to this embodiment, the surface of the substrate 1 (copper oxide film 1d) is formed in a corrugated shape having arithmetic mean roughness (Ra) of about 10 μm to about 20 μm.

A first resin layer 2, mainly composed of epoxy resin, having a thickness of about 60 μm to about 160 μm is formed on the corrugated surface of the substrate 1 (copper oxide film 1d). The first resin layer 2 functions as an insulating layer. The thermal expansion coefficient of the first resin layer 2 is about 17 ppm/° C. to about 18 ppm/° C. The first resin layer 2 is an example of the “insulating layer” or the “first insulating layer” in the present invention.

According to this embodiment, a filler having a large diameter of at least about 30 μm is added to the first resin layer 2, in order to increase the thermal conductivity of the first resin layer 2 mainly composed of epoxy resin. This filler is prepared from alumina (Al₂O₃), silica (SiO₂), aluminum nitride (AlN), silicon nitride (SiN) or boron nitride (BN). The weight filling factor of the filler is about 60% to about 80%. When the filler such as alumina or silica is added, the epoxy resin exhibits thermal conductivity of about 2 W/(m·K), which is higher than the thermal conductivity (about 0.6 W/(m·K)) of epoxy resin containing no filler.

According to this embodiment, five via holes 2a of about 100 μm in diameter passing through the first resin layer 2 are formed in a prescribed region of the first resin layer 2 located under an LSI chip 9 described later. Two via holes 2b of about 100 μm in diameter passing through the first resin layer 2 are formed in another prescribed region of the first resin layer 2 located under a chip resistor 10 described later. The via holes 2a and 2b are examples of the “opening” in the present invention. A first conductive layer 3 of copper having a thickness of about 15 μm and including thermal via portions 3a and 3b and wiring portions 3c is formed on still another prescribed region of the first resin layer 2. The first conductive layer 3 is an example of the “first conductive layer” in the present invention, and the wiring portions 3c are examples of the “first wire” in the present invention. The thermal via portion 3a is arranged in the region located under the LSI chip 9, and has portions embedded in the via holes 2a, to be in contact with the surface of the substrate 1. The thermal via portions 3b are embedded in the via holes 2b located in the region under the chip resistor 10. The thermal via portions 3a and 3b of the first conductive layer 3 have functions of releasing heat toward the substrate 1. The first resin layer 2 partially receiving the first conductive layer 3 in the via holes 2a and 2b exhibits thermal conductivity of about 6 W/(m·K) to about 8 W/(m·K). The wiring portions 3c of the first conductive layer 3 are arranged on regions separated from ends of the thermal via portion 3a at prescribed intervals.

According to this embodiment, a second resin layer 4 identical in thickness and composition to the aforementioned first resin layer 2 is formed to cover the first conductive layer 3, while a second conductive layer 5 of copper having the same thickness as the aforementioned first conductive layer 3 is formed on a prescribed region of the second resin layer 4. The second resin layer 4 and the second conductive layer 5 have structures for transferring heat to the thermal via portion 3a of the first conductive layer 3. The second resin layer 4 is an example of the “insulating layer” or the “second insulating layer” in the present invention, and the second conductive layer 5 is an example of the “second conductive layer” in the present invention.

More specifically, five via holes 4a of about 100 μm in diameter passing through the second resin layer 4 are formed in a region of the second resin layer 4 located under the LSI chip 9. The five via holes 4a are formed in positions corresponding to the five via holes 2a respectively. Two via holes 4b of about 100 μm in diameter passing through the second resin layer 4 are formed in a region of the second resin layer 4 corresponding to the wiring portions 3c of the first conductive layer 3. The second conductive layer 5 includes a thermal via portion 5a, wire bonding portions 5b and wiring portions 5c and 5d. The wiring portion 5d is an example of the “second wire” in the present invention. The thermal via portion 5a of the second conductive layer 5 is arranged on the region located under the LSI chip 9, and has portions embedded in the via holes 4a, to be in contact with the surface of the thermal via portion 3a of the first conductive layer 3. The thermal via portion 5a of the second conductive layer 5 has a function of transferring heat generated in the LSI chip 9 and the chip resistor 10 to the thermal via portion 3a of the first conductive layer 3 thereby releasing the same. The wire bonding portions 5b of the second conductive layer 5 are arranged on regions corresponding to the via holes 4b, and have portions embedded in the via holes 4b, to be in contact with the surfaces of the wiring portions 3c of the first conductive layer 3. The wiring portion 5c of the second conductive layer 3 is arranged on the region located under the chip resistor 10. The wiring portion 5d of the second conductive layer 5 is arranged on a region located under a lead 11 described later. The wiring portion 5d of the second conductive layer 5 is arranged to intersect with the wiring portions 3c of the first conductive layer 3, although this intersection is not illustrated.

A solder resist layer 6a having openings in regions corresponding to the wire bonding portions 5b and the wiring portions 5c and 5d of the second conductive layer 5 is formed to cover the second conductive layer 5. This solder resist layer 6a functions as a protective film for the second conductive layer 5. The solder resist layer 6a consists of thermosetting resin such as a melamine derivative, a liquid crystal polymer, epoxy resin, PPE (polyphenylene ether) resin, polyimide resin, fluororesin, phenol resin or polyamide bismaleimide. The liquid crystal polymer, epoxy resin or melamine derivative having an excellent high-frequency characteristic is preferable as the material for the solder resist layer 6a. A filler such as SiO₂ may be added to the solder resist layer 6a. The LSI chip 9 is mounted on the solder resist layer 6a located on the thermal via portion 5a of the second conductive layer 5 through a third resin layer 6 of epoxy resin having a thickness of about 20 μm. The LSI chip 9 employing a single-crystalline silicon substrate (not shown) has a thermal expansion coefficient of about 4 ppm/° C. This LSI chip 9 is electrically connected to the wire bonding portions 5b of the second conductive layer 5 through wires 7. The chip resistor 10 is mounted on the wiring portion 5c of the second conductive layer 5 through a fusion layer 8a of brazing filler metal such solder, and electrically connected to the wiring portion 5c through the fusion layer 8a. The LSI chip 9 and the chip resistor 10 are examples of the “circuit element” in the present invention. The lead 11 is mounted on the wiring portion 5d of the second conductive layer 5 through another fusion layer 8b of brazing filler metal such as solder and electrically connected to the wiring portion 5d through the fusion layer 8b.

As shown in FIGS. 1 and 2, a fourth resin layer 12 of epoxy resin is formed to cover the LSI chip 9 and the chip resistor 10, in order to protect the LSI chip 9 and the chip resistor 10 mounted in the hybrid integrated circuit device. A plurality of leads 11 are provided on one side of the hybrid integrated circuit device, as shown in FIG. 1.

According to this embodiment, as hereinabove described, the substrate 1 is formed to have the corrugated surface while the first resin layer 2 mainly composed of epoxy resin for serving as an insulating layer is formed on the corrugated surface of the substrate 1, whereby the contact area between the substrate 1 and the first resin layer 2 can be increased. Thus, adhesiveness between the substrate 1 and the first resin layer 2 can be improved. Consequently, the first resin layer 2 serving as an insulating layer can be inhibited from separating from the substrate 1.

According to this embodiment, further, the substrate 1 including the lower and upper metal layers 1a and 1c of copper having the thermal expansion coefficients of about 12 ppm/° C. and the intermediate metal layer 1b of the invar alloy having the thermal expansion coefficient of about 0.2 ppm/° C. to about 5 ppm/° C. is employed while the thicknesses of the lower, intermediate and upper metal layers 1a, 1b and 1c are adjusted in the ratios 1:1:1 so that the thermal expansion coefficient of the substrate 1 is about 6 ppm/° C. to about 8 ppm/° C., whereby the thermal expansion coefficient (about 6 ppm/° C. to about 8 ppm/° C.) of the substrate 1 can be approached to both of the thermal expansion coefficient (about 4 ppm/° C.) of the LSI chip 9 and the thermal expansion coefficient (about 17 ppm/° C. to about 18 ppm/° C.) of the first resin layer 2. Thus, the first resin layer 2 can be inhibited from separating from the substrate 1 due to difference in thermal expansion coefficient between the substrate 1 and the LSI chip 9 and the first resin layer 2.

According to this embodiment, in addition, the surface of the substrate 1 (upper metal layer 1c) is oxidized to form the copper oxide film 1d on the surface of the substrate 1 (upper metal layer 1c) so that the copper oxide film 1d on the surface of the substrate 1 functions as another insulating layer when the first resin layer 2 located between the substrate 1 and the wiring portions 3c of the first conductive layer 3 is deteriorated in insulation property, whereby the dielectric voltage between the substrate 1 and the wiring portions 3c of the first conductive layer 3 can be inhibited from reduction. Further, the thickness of the copper oxide film 1d on the surface of the substrate 1 (upper metal layer 1c) is set to about 2 μm to about 3 μm so that adhesiveness to the upper metal layer 1c is increased beyond that of a copper oxide film having a thickness exceeding about 3 μm, whereby the copper oxide film 1d can be inhibited from separation.

According to this embodiment, further, the filler such as alumina or silica is added to the first and second resin layers 2 and 4 mainly composed of epoxy resin for increasing the thermal conductivity of the first and second resin layers 2 and 4, whereby the first and second resin layers 2 and 4 can be improved in heat releasability. When the contact area between the substrate 1 and the first resin layer 2 is reduced due to the filler added to the first resin layer 2 and located in the vicinity of the interface between the first resin layer 2 and the substrate 1, the contact area between the substrate 1 and the first resin layer 2 is increased due to the corrugated surface of the substrate 1, whereby the adhesiveness between the substrate 1 and the first resin layer 2 can be inhibited from reduction despite the filer added to the first resin layer 2.

According to this embodiment, further, the thermal via portions 5a and 3a are so formed on the region of the first resin layer 2 located under the LSI chip 9 that a large quantity of heat generated from the LSI chip 9 can be easily transferred and released to the substrate 1 through the thermal via portions 5a and 3a. In addition, the thermal via portions 3b coming into contact with the surface of the substrate 1 are so formed in the region of the first resin layer 2 located under the chip resistor 10 that a large quantity of heat generated from the chip resistor 10 can be easily released toward the substrate 1 through the thermal via portions 3b.

According to this embodiment, further, the first resin layer 2 and the first conductive layer 3 are successively formed on the surface of the substrate 1 while the second resin layer 4 and the second conductive layer 5 are successively formed on the first conductive layer 3 so that the wiring portions 3c and 5d of the first and second conductive layers 3 and 5 can be insulated from each other through the second resin layer 4. Also when the wiring portions 3c and 5d of the first and second conductive layers 3 and 5 intersect with each other in a plan view, therefore, the wiring portions 3c and 5d of the first and second conductive layers 3 and 5 can be inhibited from an electric short circuit. Consequently, the degree of freedom in extension of the wiring portions 3c and 5d as well as the wiring density thereof can be improved.

A process of fabricating the hybrid integrated circuit device according to this embodiment is now described with reference to FIGS. 2 to 15.

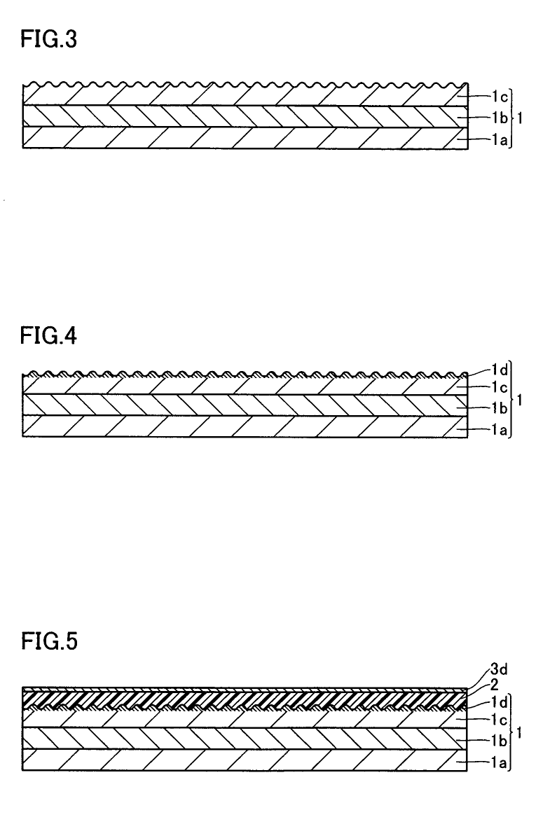

First, the substrate 1 including the lower and upper metal layers 1a and 1c of copper having the thermal expansion coefficients of about 12 ppm/° C. and the intermediate metal layer 1b of the invar alloy having the thermal expansion coefficient of about 0.2 ppm/° C. to about 5 ppm/° C. is formed as shown in FIG. 3. More specifically, the intermediate metal layer 1b is arranged and pressed between the lower and upper metal layers 1a and 1c, thereby forming the substrate 1 of the cladding material having the three-layer structure. At this time, the thicknesses of the lower, intermediate and upper metal layers 1a, 1b and 1c are so set that the thickness of the substrate 1 is about 100 μm to about 3 mm (about 1.5 mm, for example) respectively. According to this embodiment, the thicknesses of the lower, intermediate and upper metal layers 1a, 1b and 1c are adjusted in the ratios 1:1:1. Thus, the substrate 1 has the thermal expansion coefficient of about 6 ppm/° C. to about 8 ppm/° C.

Thereafter the surface of the upper metal layer 1c forming the uppermost layer constituting the substrate 1 is roughened into the corrugated shape having the arithmetic mean roughness Ra of about 10 μm to about 20 μm by sandblasting, wet blasting or wet etching. The sandblasting is a technique of spraying abrasive to a work by accelerating the abrasive with compressed air from a compressor. The wet blasting is a technique of spraying abrasive to a work by accelerating a liquid mixed with the abrasive with compressed air from a compressor.

As shown in FIG. 4, the corrugated surface of the upper metal layer 1c forming the uppermost layer constituting the substrate 1 is oxidized by heat-treating the substrate 1 under a temperature condition of one hundred and several 10 degrees. Thus, the corrugated surface of the upper metal layer 1c forming the uppermost layer of the substrate 1 is converted to the copper oxide film 1d having the thickness of about 0.1 μm to about 0.3 μm.

As shown in FIG. 5, epoxy resin containing the filler such as alumina or silica added thereto is applied to the corrugated surface of the substrate 1 (copper oxide film 1d), thereby forming the first resin layer 2 having the thickness of about 60 μm to about 160 μm. Thereafter a copper foil film 3d having a thickness of about 3 μm is pressure-bonded onto the first resin layer 2.

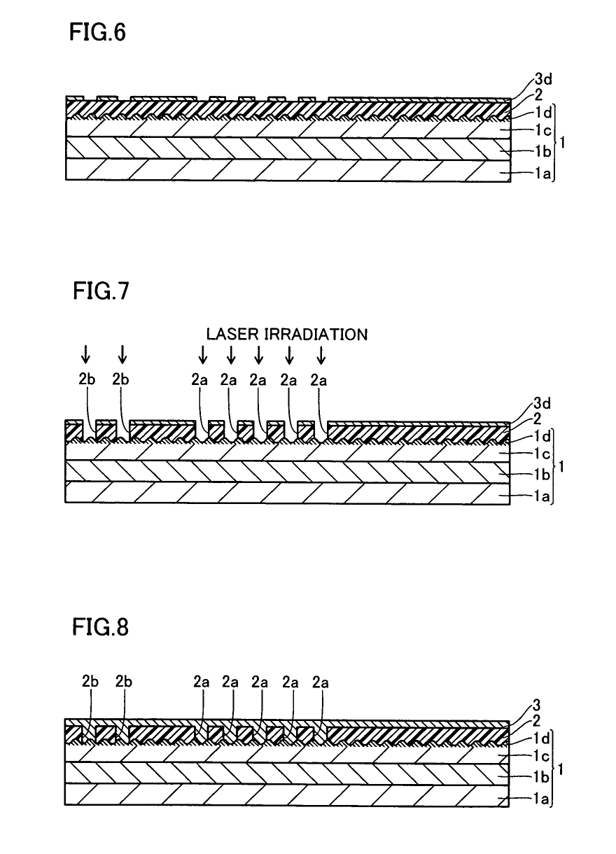

As shown in FIG. 6, portions of the copper foil film 3d located on regions for forming the via holes 2a and 2b (see FIG. 2) are removed by photolithography and etching. Thus, the regions of the first resin layer 2 for forming the via holes 2a and 2b are exposed.

As shown in FIG. 7, a carbon dioxide laser beam or an excimer laser beam is applied from above the copper foil film 3d, thereby removing the regions reaching the surface of the substrate 1 from the exposed surface portions of the first resin layer 2. Thus, the five via holes 2a and the two via holes 2b of about 100 μm in diameter passing through the first resin layer 2 are formed in the first resin layer 2. The via holes 2a and 2b are provided for forming the thermal via portions 3a and 3b described later respectively.

As shown in FIG. 8, the upper surface of the copper foil film 3d (see FIG. 7) and the inner surfaces of the via holes 2a and 2b are plated with copper by electroless plating, with a thickness of about 0.5 μm. Then, the upper surface of the copper foil film 3d and the inner surfaces of the via holes 2a and 2b are plated by electrolytic plating. According to this embodiment, an inhibitor and a promoter are added to a plating solution so that the upper surface of the copper foil film 3d adsorbs the inhibitor while the inner surfaces of the via holes 2a and 2b adsorb the promoter. Thus, the copper plating films formed on the inner surfaces of the via holes 2a and 2b can be increased in thickness, so that copper can be embedded in the via holes 2a and 2b. Consequently, the first conductive layer 3 having the thickness of about 15 μm is formed on the first resin layer 2 and partially embedded in the via holes 2a and 2b, as shown in FIG. 8.

In the aforementioned copper plating step, the plating solution can be inhibited from deterioration resulting from elution of the component of the intermediate metal layer 1b of the invar alloy, due to the substrate 1 obtained by holding the intermediate metal layer 1b of the invar alloy containing Fe and Ni between the lower and upper metal layers 1a and 1b employed according to this embodiment.

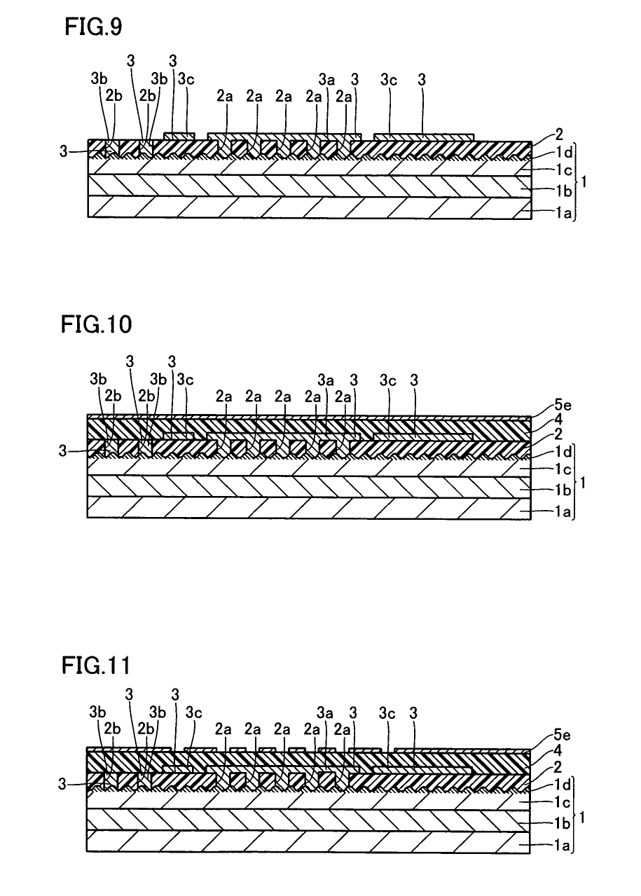

As shown in FIG. 9, the first conductive layer 3 is patterned by photolithography and etching. Thus, the thermal via portions 3a and 3b are formed on the regions located under the LSI chip 9 (see FIG. 2) and the chip resistor 10 (see FIG. 2) respectively while the wiring portions 3c are formed on the regions separated from the ends of the thermal via portion 3a at the prescribed intervals.

As shown in FIG. 10, the epoxy resin containing the filler such as alumina or silica added thereto is applied to cover the first conductive layer 3, thereby forming the second resin layer 4 having the thickness of about 60 μm to about 160 μm. Thereafter another copper foil film 5e having a thickness of about 3 μm is press-bonded onto the second resin layer 4.

As shown in FIG. 11, portions of the copper foil film 5e located on the regions for forming the via holes 4a and 4b (see FIG. 2) are removed by photolithography and etching. Thus, the regions of the second resin layer 4 for forming the via holes 4a and 4b are exposed.

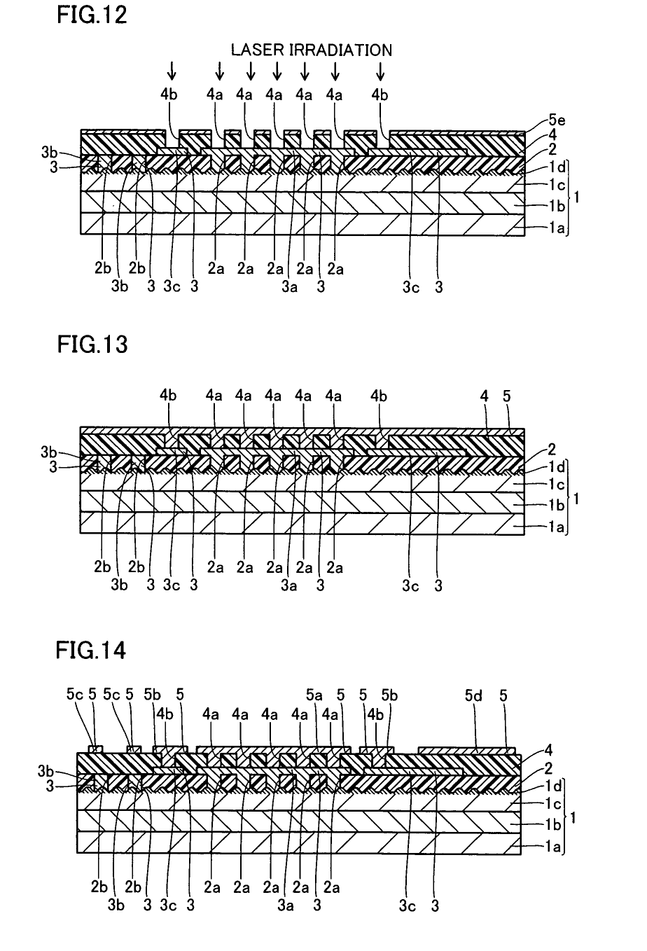

As shown in FIG. 12, a carbon dioxide laser beam or an excimer laser beam is applied from above the copper foil film 5e, thereby removing the regions reaching the surface of the first conductive layer 3 from the exposed surface portions of the second resin layer 4. Thus, the five via holes 4a and the two via holes 4b of about 100 μm in diameter passing through the second resin layer 4 are formed in the second resin layer 4.

As shown in FIG. 13, the upper surface of the copper foil film 5e (see FIG. 12) and the inner surfaces of the via holes 4a and 4b are plated with copper by electroless plating, with a thickness of about 0.5 μm. Then, the upper surface of the copper foil film 5e and the inner surfaces of the via holes 4a and 4b are plated by electrolytic plating. At this time, an inhibitor and a promoter are added to a plating solution so that the upper surface of the copper foil film 5e adsorbs the inhibitor while the inner surfaces of the via holes 4a and 4b adsorb the promoter. Thus, the copper plating films formed on the inner surfaces of the via holes 4a and 4b can be increased in thickness, so that copper can be embedded in the via holes 4a and 4b. Consequently, the second conductive layer 5 having the thickness of about 15 μm is formed on the second resin layer 4 and partially embedded in the via holes 4a and 4b.

As shown in FIG. 14, the second conductive layer 5 is patterned by photolithography and etching. Thus, the thermal via portion 5a located on the region under the LSI chip 9 (see FIG. 2), the wire bonding portions 5b located on the regions separated from the ends of the thermal via portion 5a at the prescribed intervals and the wiring portions 5c and 5d located on the regions under the chip resistor 10 (see FIG. 2) and the lead 11 (see FIG. 2) respectively are formed.

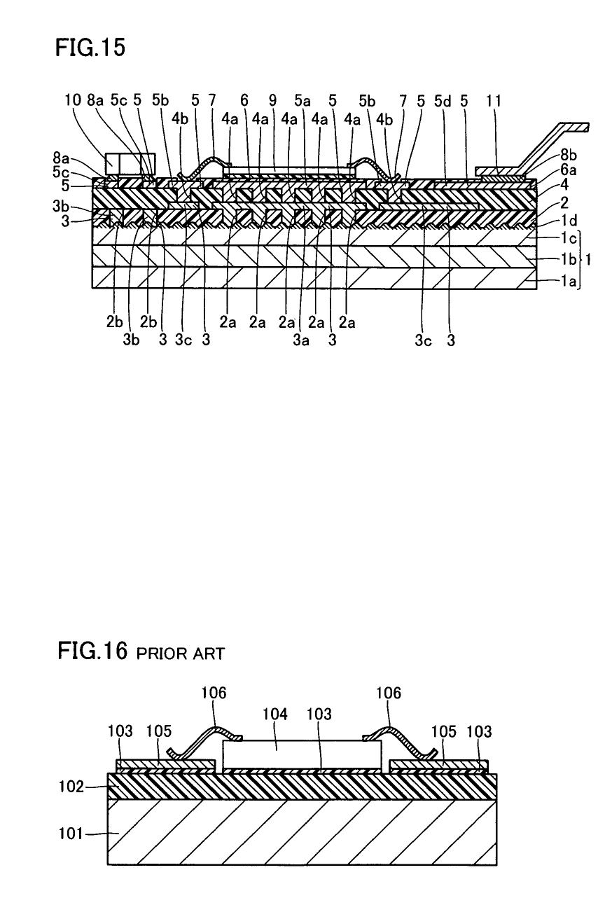

As shown in FIG. 15, the solder resist layer 6a having the openings in the regions corresponding to the wire bonding portions 5b and the wiring portions 5c and 5d of the second conductive layer 5 respectively is formed to cover the second conductive layer 5. The LSI chip 9 is mounted on the portion of the solder resist layer 6a located on the thermal via portion 5a of the second conductive layer 5 through the third resin layer 6 of epoxy resin having the thickness of about 50 μm. After this mounting of the LSI chip 9, the thickness of the third resin layer 6 is about 20 μm. Thereafter the LSI chip 9 and the wire bonding portions 5b of the second conductive layer 5 are electrically connected with each other through the wires 7. Further, the chip resistor 10 is mounted on the wiring portion 5c of the second conductive layer 5 through the fusion layer 8a of the brazing filler metal such as solder. In addition, the lead 11 is mounted on the wiring portion 5d of the second conductive layer 5 through the fusion layer 8b of the brazing filler metal such as solder. The chip resistor 10 and the lead 11 are electrically connected to the wiring portions 5c and 5d through the fusion layers 8a and 8b respectively.

Finally, the fourth resin layer 12 of epoxy resin is formed to cover the LSI chip 9 and the chip resistor 10 in order to protect the LSI chip 9 and the chip resistor 10 provided on the substrate 1, thereby completing the hybrid integrated circuit device according to this embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the present invention is applied to the hybrid integrated circuit device mounted with the LSI chip and the chip resistor in the aforementioned embodiment, the present invention is not restricted to this bus is also applicable to another type of hybrid integrated circuit device mounted with circuit elements other than an LSI chip and a chip resistor, or to a semiconductor integrated circuit device other than a hybrid integrated circuit device.

While the copper oxide film is formed on the surface of the substrate by oxidizing the surface of the substrate in the aforementioned embodiment, the present invention is not restricted to this but the surface of the substrate may not be oxidized. Alternatively, a copper nitride film may be formed on the surface of the substrate by nitriding the surface of the substrate.

While the lower and upper metal layers of copper hold the intermediate layer of the invar alloy (Fe—Ni alloy) therebetween in the substrate according to the aforementioned embodiment, the present invention is not restricted to this but lower and upper metal layers of aluminum may alternately hold the intermediate metal layer of the invar alloy therebetween in the substrate. Further alternatively, a lower metal layer (upper metal layer) of copper and an upper metal layer (lower metal layer) of aluminum may hold the intermediate metal layer of the invar alloy therebetween in the substrate. When the upper metal layer constituting the substrate consists of aluminum, an aluminum oxide film formed on the surface of the substrate (upper metal layer) for functioning as an insulating layer can be densified by oxidizing the surface of the substrate (upper metal layer) by anodization. In addition, the intermediate metal layer may alternatively consist of an alloy (the so-called super-invar alloy) of Fe containing about 32% of Ni and about 5% of Co or another alloy (the so-called covar alloy) of Fe containing about 29% of Ni and about 17% of Co, in place of the invar alloy.

While the thicknesses of the lower, intermediate and upper metal layers constituting the substrate are set to the ratios 1:1:1 in the aforementioned embodiment, the present invention is not restricted to this but the thicknesses of the lower, intermediate and upper metal layers may alternatively be set to 1:3:1.

While the present invention is applied to the circuit device of the two-layer structure having the second insulating layer and the second conductive layer successively formed on the first conductive layer in the aforementioned embodiment, the present invention is not restricted to this but is also applicable to a circuit device having a single-layer structure. The present invention is further applicable to a circuit device having a third insulating layer and a third conductive layer further successively formed on a second conductive layer. The present invention is further applicable to a circuit device having a multilayer structure with at least four conductive layers and four insulating layers.

While the filler having the diameter of at least about 30 μm is added to the first resin layer in the aforementioned embodiment, the present invention is not restricted to this but fillers having diameters of about 30 μm and about 2 μm respectively may be mixed into the first resin layer.

While the substrate has the three-layer structure including the lower and upper metal layers of copper and the intermediate metal layer of the invar alloy in the aforementioned embodiment, the present invention is not restricted to this but the substrate may alternatively have a multilayer structure including at least four metal layers. Further, the substrate may include at least one of a resin layer, a ceramics layer and a semiconductor layer.

1. A circuit device comprising:
a substrate mainly constituted of metal including a first metal layer having a first thermal expansion coefficient, a second metal layer, formed on said first metal layer, having a second thermal expansion coefficient different from said first thermal expansion coefficient of said first metal layer and a third metal layer, formed on said second metal layer, having a third thermal expansion coefficient different from said second thermal expansion coefficient of said second metal layer;
an insulating layer formed on said substrate;
a conductive layer formed on said insulating layer; and
a circuit element electrically connected to said conductive layer.

2. The circuit device according to claim 1, wherein
the thicknesses of said first metal layer, said second metal layer and said third metal layer constituting said substrate are so adjusted that the thermal expansion coefficient of said substrate approaches both of the thermal expansion coefficient of said insulating layer and the thermal expansion coefficient of said circuit element.

3. The circuit device according to claim 1, wherein
said second thermal expansion coefficient of said second metal layer is smaller than said first thermal expansion coefficient of said first metal layer and said third thermal expansion coefficient of said third metal layer.

4. The circuit device according to claim 1, wherein
said insulating layer includes an insulating layer mainly composed of resin.

5. The circuit device according to claim 4, wherein
a filler is added to said insulating layer mainly composed of resin for increasing the thermal conductivity of said insulating layer.

6. The circuit device according to claim 1, wherein
said insulating layer includes an opening provided in a region located under said circuit element to reach the surface of said substrate, and
said conductive layer provided on said insulating layer is formed to be in contact with the surface of said substrate through said opening, and has a function of transferring heat to said substrate through said opening.

7. The circuit device according to claim 6, wherein
the components of said first metal layer and said third metal layer are identical to the component of said conductive layer.

8. The circuit device according to claim 1, wherein
said insulating layer includes a first insulating layer formed on said substrate and a second insulating layer formed on said first insulating layer, and
said conductive layer includes a first conductive layer formed between said first insulating layer and said second insulating layer and a second conductive layer formed on said second insulating layer.

9. The circuit device according to claim 8, further including a first wire constituted of said first conductive layer and a second wire constituted of said second conductive layer, wherein
said first wire and said second wire intersect with each other in a plan view.

10. The circuit device according to claim 1, wherein
said substrate has a corrugated surface.

11. The circuit device according to claim 1, wherein
the surface of said substrate is oxidized or nitrided.

12. A circuit device comprising:
a substrate, having a corrugated surface, mainly constituted of metal;
an insulating layer formed on said corrugated surface of said substrate;
a conductive layer formed on said insulating layer; and
a circuit element electrically connected to said conductive layer.

13. The circuit device according to claim 12, wherein
said insulating layer includes an insulating layer mainly composed of resin.

14. The circuit device according to claim 13, wherein
a filler is added to said insulating layer mainly composed of resin for increasing the thermal conductivity of said insulating layer.

15. The circuit device according to claim 12, wherein
said insulating layer includes an opening provided in a region located under said circuit element to reach the surface of said substrate, and
said conductive layer provided on said insulating layer is formed to be in contact with the surface of said substrate through said opening, and has a function of transferring heat to said substrate through said opening.

16. The circuit device according to claim 12, wherein
said insulating layer includes a first insulating layer formed on the surface of said substrate and a second insulating layer formed on said first insulating layer, and
said conductive layer includes a first conductive layer formed between said first insulating layer and said second insulating layer and a second conductive layer formed on said second insulating layer.

17. The circuit device according to claim 16, further including a first wire constituted of said first conductive layer and a second wire constituted of said second conductive layer, wherein
said first wire and said second wire intersect with each other in a plan view.

18. The circuit device according to claim 12, wherein
said substrate includes:
a first metal layer having a first thermal expansion coefficient,
a second metal layer, formed on said first metal layer, having a second thermal expansion coefficient different from said first thermal expansion coefficient of said first metal layer, and
a third metal layer, formed on said second metal layer, having a third thermal expansion coefficient different from said second thermal expansion coefficient of said second metal layer.

19. The circuit device according to claim 12, wherein
said corrugated surface of said substrate is oxidized or nitrided.

20. A circuit device comprising:
a substrate, having an oxidized or nitrided surface, mainly constituted of metal;
an insulating layer formed on said oxidized or nitrided surface of said substrate;
a conductive layer formed on said insulating layer; and
a circuit element electrically connected to said conductive layer.

21. The circuit device according to claim 20, wherein
said oxidized or nitrided surface of said substrate is formed in a corrugated shape.

22. The circuit device according to claim 20, wherein
said insulating layer includes an insulating layer mainly composed of resin.

23. The circuit device according to claim 22, wherein
a filler is added to said insulating layer mainly composed of resin for increasing the thermal conductivity of said insulating layer.

24. The circuit device according to claim 20, wherein
said insulating layer includes an opening provided in a region located under said circuit element to reach the surface of said substrate, and
said conductive layer provided on said insulating layer is formed to be in contact with the surface of said substrate through said opening, and has a function of transferring heat to said substrate through said opening.

25. The circuit device according to claim 20, wherein
said insulating layer includes a first insulating layer formed on the surface of said substrate and a second insulating layer formed on said first insulating layer, and
said conductive layer includes a first conductive layer formed between said first insulating layer and said second insulating layer and a second conductive layer formed on said second insulating layer.

26. The circuit device according to claim 25, further including a first wire constituted of said first conductive layer and a second wire constituted of said second conductive layer, wherein
said first wire and said second wire intersect with each other in a plan view.

27. The circuit device according to claim 20, wherein
said substrate includes:
a first metal layer having a first thermal expansion coefficient,
a second metal layer, formed on said first metal layer, having a second thermal expansion coefficient different from said first thermal expansion coefficient of said first metal layer, and
a third metal layer, formed on said second metal layer, having a third thermal expansion coefficient different from said second thermal expansion coefficient of said second metal layer.
